(19) United States
(12) Patent Application Publication
(10) Pub. No.: US 2003/0209758 A1
(43) Pub. Date: Nov. 13, 2003

(54) Transistor of semiconductor device, and method for forming the same

(76) Inventors: Ga Won Lee, Kyoungki-do (KR); Jae Hee Lee, Kyoungki-do (KR)

Correspondence Address: JACOBSON HOLMAN PLLC, 400 SEVENTH STREET N.W., SUITE 600, WASHINGTON, DC, 20004, US

(21) Appl. No.: 10/329,518

(22) Filed: Dec. 27, 2002

(30) Foreign Application Priority Data
May 13, 2002 (KR) 2002-26230

(51) Int. Cl. H01L 29/76

(52) U.S. Cl. 257/336

(57) ABSTRACT

The present invention discloses a transistor of a semiconductor device and a method for forming the same which provides improved electrical characteristics of the transistor and allow a high integration density of the device wherein a super steep halo doped region is formed according to a halo implant process using a gate and a dummy gate as masks by reducing a halo dose in source/drain junction regions in order to prevent deterioration of characteristic of the device.

### BACKGROUND OF THE INVENTION

1. Field of the Invention

The present invention relates to a transistor of a semiconductor device and a method for forming the same, and in particular to a technique for improving a property of a giga level DRAM or ULSI device by forming a super steep halo implanted MOSFET for obtaining a short channel margin, reducing junction leakage current and increasing a break down voltage when forming a high density transistor in a region other than a high pattern density region such as a cell region, namely a peripheral circuit region or a logic unit, and by applying it to a general transistor.

2. Description of the Background Art

A channel length of a transistor is decreased due to a high integration density of a semiconductor device. However, it is very difficult to reduce leakage current and achieve high integration density at the same time.

This is because the junction leakage current is considerably increased when an implant concentration of a substrate is increased to prevent a short channel effect resulting from reduction of the channel length.

The increased junction leakage current generates large increase in power consumption.

In order to solve the foregoing problem, a halo process for selectively increasing an implant concentration only in a source and a drain of a substrate has been introduced to MOSFET production.

FIGS. 1a and 1b are cross-sectional views illustrating a conventional method for forming a transistor of a semiconductor device, wherein a peripheral circuit region or a logic region is shown. Generally, the peripheral circuit region or the logic unit has a structure wherein one word line passes in one active region.

Referring to FIG. 1a, an device isolation film 13 defining an active region is formed on a semiconductor substrate 11.

A gate oxide film 15 and a gate 17 are patterned on the active region of the semiconductor substrate 11.

Here, the gate 17 is formed by depositing a conductive layer for gate on the gate oxide film 15, and etching the conductive layer for gate according to a photoetching process using a gate mask (not shown).

Thereafter, a low concentration impurity junction region, namely an LDD region 19 is formed by ion-implanting a low concentration impurity into the semiconductor substrate 11 using the gate 17 as a mask.

A halo doped region 21 is formed below the LDD region 19 by using the gate 17 as a mask.

Here, the halo doped region 21 is formed between the lower portion of the gate 17 and the device isolation film 13 by tilt-implanting ions four times with 0°, 90°, 180° and 270 rotations using the gate 17 as a mask.

Referring to FIG. 1b, an insulating film spacer 23 is formed on the sidewalls of the gate 17.

A high concentration impurity junction region 25 is formed by ion-implanting a high concentration impurity into the semiconductor substrate 11 using the insulating film spacer 23 and the gate 17 as a mask, thereby forming source/drain junction regions 19 and 25 having LDD structure.

The conventional method for forming the transistor of the semiconductor device has disadvantages in that the junction leakage current is increased and the junction break down voltage is lowered due to a high implant concentration in the source/drain junction regions. As a result, a property and reliability of the device are degraded, and thus a high integration density of the device cannot be achieved.

### SUMMARY OF THE INVENTION

Accordingly, it is an object of the present invention to provide a transistor of a semiconductor device and a method for forming the same which allows a high integration density of the semiconductor device wherein a super steep halo doped region is formed by reducing a halo dose in source/drain junction regions to prevent deterioration of characteristic of the semiconductor device.

In order to achieve the above-described object of the invention, there is provided a transistor of a semiconductor device including: an device isolation film defining an active region of a semiconductor substrate; a gate provided in the active region; dummy gates provided at both sides of the gate, wherein the dummy gates are spaced apart from the gate at a distance of ‘d’ has a height of ‘h’, the dummy gates being positioned to overlap the device isolation film and the active region; an LDD region formed in the semiconductor substrate between the gate and the dummy gate; and a halo doped region formed under a portion of the LDD region below the gate and the dummy gates, wherein a size of the halo doped region is controlled according to the distance of ‘d’ and the height of ‘h’.

According to another aspect of the invention, a transistor of a semiconductor device includes: an device isolation film defining an active region of a semiconductor substrate; a gate provided in the active region; dummy gates provided at both sides of the gate, wherein the dummy gates are spaced apart from the gate at a distance of ‘d’ has a height of ‘h’, the dummy gates being positioned to overlap the device isolation film and the active region; an insulating film filling a space between the gate and the dummy gate; an LDD region formed in the semiconductor substrate between the gate and the dummy gate; and a halo doped region formed under a portion of the LDD region below the gate and the dummy gates, wherein a size of the halo doped region is controlled according to the distance of ‘d’ and the height of ‘h’.

According to yet another aspect of the invention, a method for forming a transistor of a semiconductor device includes the steps of: forming a stacked structure of a gate oxide film and a gate, and dummy gates at both sides of the gate on a semiconductor substrate using a gate mask; forming an LDD region in the semiconductor substrate using the gate and the dummy gate as masks; and performing a halo implant process to form a halo doped region under a portion of the LDD region below the gate and the dummy gate using the gate and the dummy gate as masks, wherein the dummy gates are formed in parallel to the gate and spaced apart from the gate by a distance of ‘d’, the dummy gates overlap an active region and an device isolation region of the semiconductor device, the step of performing a halo implant process is a tilt ion-implanting process, the step of performing a halo implant process comprises rotating the semiconductor substrate by 0° and 180° to tilt-implant ions into the semiconductor substrate at the right and left sides of the gate, and a size of the halo implanted region is controlled according to the distance of ‘d’ and the height of the dummy gate.

According to yet another aspect of the invention, a method for forming a transistor of a semiconductor device includes the steps of: forming a stacked structure of a gate oxide film and a gate, and dummy gates at both sides of the gate on a semiconductor substrate using a gate mask; forming an LDD region in the semiconductor substrate using the gate and the dummy gate as masks; performing a halo implant process to form a halo doped region under a portion of the LDD region below the gate and the dummy gate using the gate and the dummy gate as masks; filling a space between the gate and the dummy gate; forming insulating film spacers on the sidewalls of the gate and the dummy gate; and ion-implanting a high concentration impurity into the semiconductor substrate by using the gate, the dummy gate and the insulating film spacer as masks to form source/drain junction regions, wherein the dummy gates are formed in parallel to the gate and spaced apart from the gate by a distance of ‘d’, the dummy gates overlap between an active region and an device isolation region of the semiconductor device, the step of performing a halo implant process is a tilt ion-implanting process, the step of performing a halo implant process comprises rotating the semiconductor substrate by 0°, 90°, 180° and 270° rotations, a size of the halo implanted region is controlled according to the distance of ‘d’ and the height of the dummy gate, and the step of forming a stacked structure of a gate oxide film and a gate and dummy gates further comprises forming hard mask layers on the gate and the dummy gate.

The principle of the present invention is that a super steep halo structure is embodied by forming a MOSFET comprising a dummy gate in a peripheral circuit region or a logic unit having a low pattern density. The super steep halo structure improves characteristics and performance of the device.

In the super steep structure, a concentration in source/drain junction regions is low, and the concentration gradually increased toward a channel, and decreased again.

A halo doping profile for obtaining a short channel margin and reducing junction leakage current by a drain electric field is controlled by the dummy gate.

For reference, the term “super steep” was introduced when a channel length of the device was reduced into sub-micron level. It refers to an abrupt profile in contrast to a broad profile in an doping profile of implantation. The super steep can be embodied when the doping profile is locally and precisely controlled.

In accordance with the present invention, a halo implant process using a dummy gate maintains a low implant concentration in source/drain junction regions while locally increasing a channel region doping concentration.

The halo doping process which is also referred to as a pocket implant process, and was proposed to control short channel effects when a channel length is decreased and channel depth is increased in the sub-micron level MOSFET. The halo doping process increases local implant concentration of the channel region by implanting a p-type impurity in NMOS and an n-type impurity in PMOS.

Since the halo implant process can reduce a depletion layer when a bias is applied, it can efficiently control the short channel effects such as drain induced barrier lowering.

To embody a halo doped region a tilt-implantation is performed, to surround the source/drain and increase implant concentration of the channel region.

### BRIEF DESCRIPTION OF THE DRAWINGS

The present invention will become better understood with reference to the accompanying drawings which are given only by way of illustration and thus are not limitative of the present invention, wherein:

FIGS. 1a and 1b are cross-sectional views illustrating a conventional method for forming a transistor of a semiconductor device;

FIGS. 2a to 2c are cross-sectional views and a plan view illustrating a method for forming a transistor of a semiconductor device for explaining the principle of the present invention;

FIG. 3 is a graph showing relations of a distance between a gate and a dummy gate and a height of the gate in a super steep structure in accordance with the present invention;

FIGS. 4a to 4d are cross-sectional views illustrating a method for forming a transistor of a semiconductor device in accordance with a first embodiment of the present invention;

FIGS. 5a and 5b are a cross-sectional view and a plan view illustrating a method for forming a transistor of a semiconductor device in accordance with a second embodiment of the present invention; and

FIGS. 6a to 6c are graphs showing boron concentration according to the depth of semiconductor substrate in accordance with the present invention.

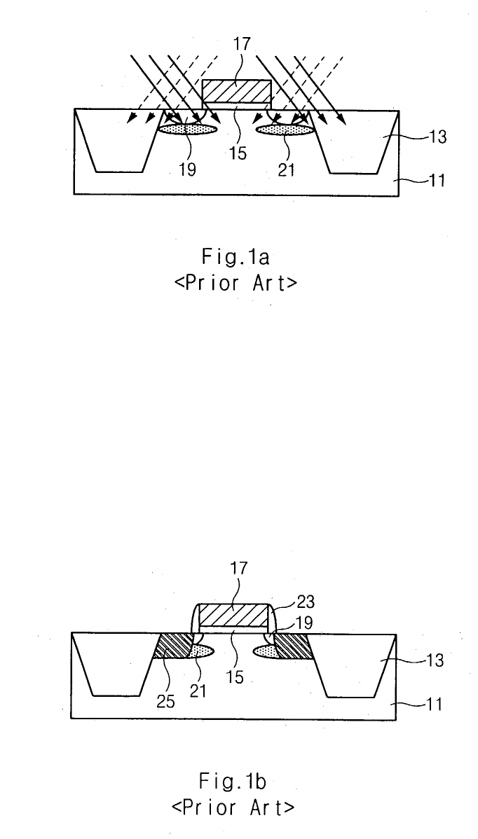

### DETAILED DESCRIPTION OF THE PREFERRED EMBODIMENTS

A transistor of a semiconductor device and a method for forming the same in accordance with preferred embodiments of the present invention will now be described in detail with reference to the accompanying drawings.

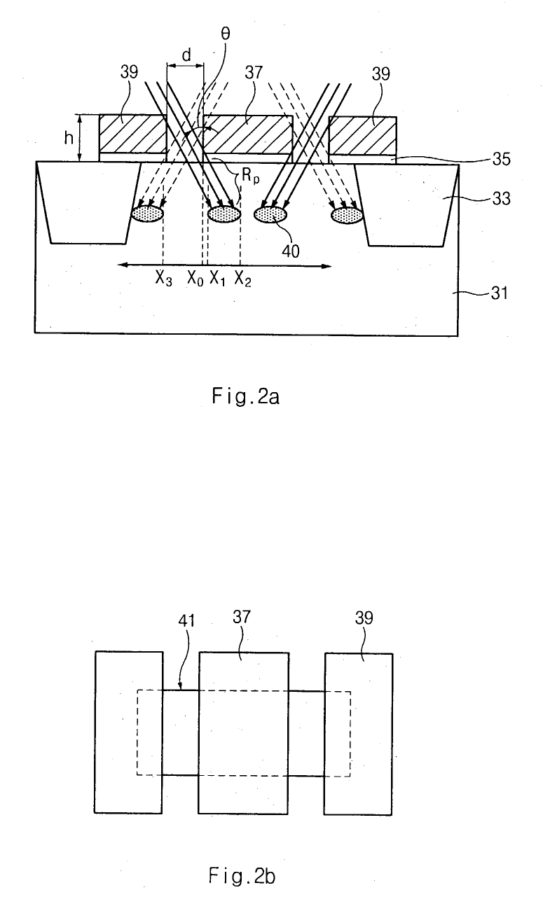

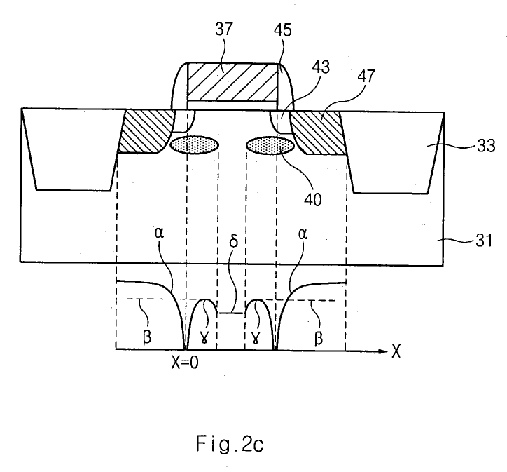

FIGS. 2a to 2c are cross-sectional views and a plan view illustrating the method for forming the transistor of the semiconductor device to explain the principle of the present invention, wherein a peripheral circuit region or a logic unit is shown.

Referring to FIG. 2a, an device isolation film 33 defining an active region is formed on a semiconductor substrate 31, and a gate 37 is formed in the active region of the semiconductor substrate 31. Here, a gate oxide film 35 is positioned between the semiconductor substrate 31 and the gate 37.

A dummy gate 39 is formed on the semiconductor substrate 31. The dummy gate 39 extends from a portion of the active region in which the gate 37 is formed to a portion of the device isolation region in which the device isolation film 33 is formed.

A height of the dummy gate 39 is ‘h’ and a distance between the dummy gate 39 and the gate 37 is ‘d’.

Thereafter, a low density impurity junction region (not shown), namely an LDD region is formed on the semiconductor substrate 31 using the gate 37 and the dummy gate 39 as masks.

A halo implanted region 40 is then formed in the semiconductor substrate 31 by performing a halo implanting process using the gate 37 and the dummy gate 39 as masks.

Here, halo implant ranges satisfy following formulas.

X₁=Rₚ×sin θ−(d−h×tan θ) Formula 1

X₂=Rₚ×sin θ Formula 2

X₃=(Rₚ×sin θ+h×tan θ) Formula 3

(where X₁, X₂ and X₃ denote halo implant ranges in X axis, Rₚ is projected range determined by a halo implant energy and θ is the tilt angle).

Thereafter, the following conditions must be satisfied for a super steep structure.

X₁>0 (or X₁>−T_{sidewall}), X₂<L_{channel}/2 Formula 4

(where a channel length of MOSFET is L_{channel} and that a thickness of an insulating film spacer of the gate is T_{sidewall})

In accordance with the present invention, ‘d’ and ‘h’ are controlled to form the super steep halo implanted region to improve characteristics and reliability of the device and achieve a high integration density of the device.

FIG. 2b is a plan view illustrating correlations among the gate 37, the dummy gate 39 and the impurity junction region 41 formed according to the process of FIG. 2a.

Referring to FIG. 2c, an insulating film spacer 45 is formed on the sidewalls of the gate 37 after the process of FIG. 2a. Thereafter high concentration impurity junction regions 47 are formed by ion-implanting a high concentration impurity into the semiconductor substrate 31 using the gate 37 and the insulating film spacer 45 as masks, thereby forming source/drain junction regions having an LDD structure.

The implant concentrations of regions to the left and right of a reference point X=0 which is one end of the gate electrode 37 are shown in FIG. 2c, where (α) denotes an implant concentration of source/drain junction regions, (β) denotes an implant concentration of a general halo implanted region, (γ) denotes an implant concentration of a super steep halo implanted region, and (δ) denotes a well implant concentration. Here, (α), (β), (γ) and (δ) are relative implant concentrations.

The dummy gate 39 is formed as a line parallel to the gate 37, or formed in the LDD structure source/drain junction regions.

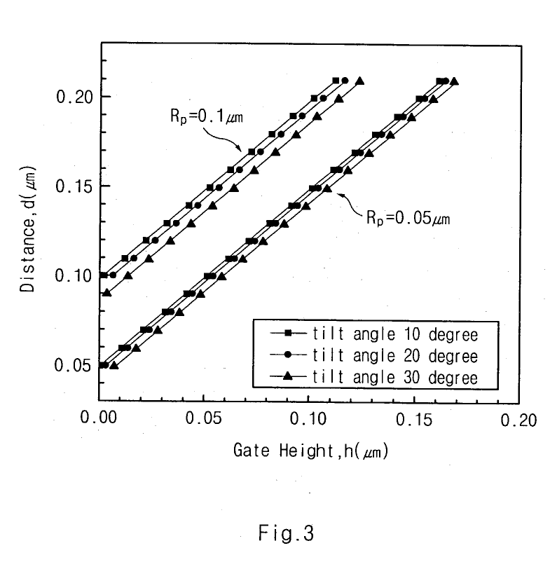

FIG. 3 is a graph showing relations between ‘d’ and ‘h’ satisfying ‘X₁=0’ wherein the halo implant process is performed using a halo implant energy of 30 KeV.

The distance between the gate and the dummy gate is increased as more the height of the gate is increased. Therefore, an area of the halo implanted region may be increased in unit device production.

Such an increase in distance can be compensated for by controlling a tilt angle of the halo implant process or the height of the gate and the dummy gate. The method for controlling the height of the gate is more efficient.

The present invention will now be explained in more detail with reference to the accompanying drawings.

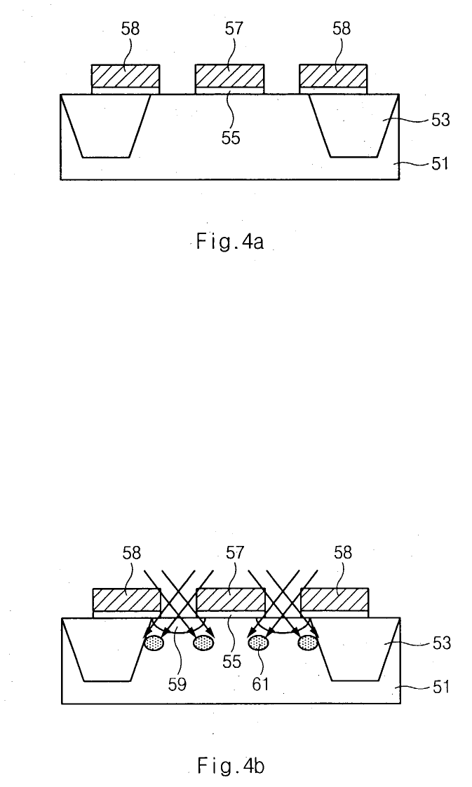

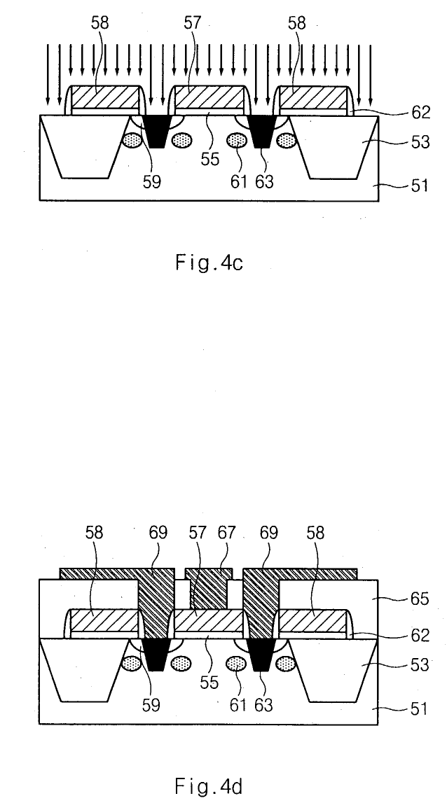

FIGS. 4a to 4d are cross-sectional views illustrating a method for forming a transistor of a semiconductor device in accordance with a first embodiment of the present invention, wherein a peripheral circuit region or a logic unit is shown.

Referring to FIG. 4a, a pad insulating film (not shown) having a stacked structure of a pad oxide film (not shown) and a pad nitride film (not shown) is formed on a semiconductor substrate 51.

A trench (not shown) is formed by etching the pad insulating film and a predetermined thickness of semiconductor substrate 51 according to a photoetching process using an device isolation mask (not shown).

A device isolation film 53 defining an active region of the semiconductor substrate is formed by filling the trench.

Thereafter, a gate oxide film 55 and a gate 57 are formed in the active region of the semiconductor substrate 51 according to a photoetching process using a word line mask, namely a gate mask (not shown).

Here, the gate mask is an exposure mask designed for a dummy gate 58 at both sides of the gate 57. Here, the dummy gate 58 is parallel to the gate 57 in the same direction.

A hard mask layer (not shown) is formed on the gate 57, and an insulating film spacer is formed in a process, which allows a subsequent self-aligned contact process.

The dummy gate 58 is formed on the device isolation film 53 and overlaps with the active region.

Referring to FIG. 4b, an LDD region 59 is formed by ion-implanting a low concentration impurity into the semiconductor substrate 51 using the gate 57 as a mask.

A halo implant process is performed on the semiconductor substrate 51 using the gate 57 as a mask.

Here, the halo implant process is performed by tilt ion-implanting impurity having a conductive type opposite to that of the impurity implanted into the LDD region 59.

Preferably, the halo tilt implanting process is performed with 0° and 180° rotations.

As shown in FIG. 4c, an insulating film spacer 62 is formed on the sidewalls of the gate 57. High concentration impurity junction regions 63 are formed by ion-implanting a high concentration impurity into the semiconductor substrate 51 using the gate 57 and the insulating film spacer 62 as masks, thereby forming source/drain junction regions having an LDD structure.

Referring to FIG. 4d, an interlayer insulating film 65 is formed on the top surface of the resulting structure, and then a source/drain contact plug 69 contacting the source/drain junction regions and a gate contact plug 67 contacting the gate 57 are formed in the same process according to a photoetching process using a contact mask.

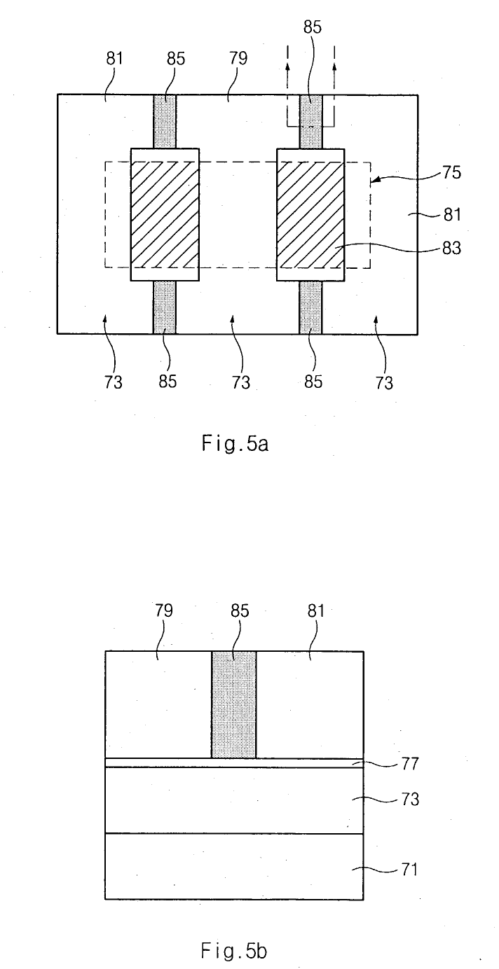

FIGS. 5a and 5b are a plan view and a cross-sectional view illustrating a method for forming a transistor of a semiconductor device in accordance with a second embodiment of the present invention, wherein a peripheral circuit region or a logic unit of the device is shown. FIG. 5b is a cross-sectional view taken along line I-I of FIG. 5a.

Referring to FIGS. 5a and 5b, an device isolation film 73 defining an active region is formed on a semiconductor substrate 71.

A gate oxide film 77 is formed on the semiconductor substrate 71.

A gate 79 and a dummy gate 81 are formed by depositing and patterning a conductive layer (not shown) for gate according to a photoetching process using a gate mask (not shown).

Here, the gate mask is an exposure mask designed to form the dummy gate 81 at both sides of the gate 79.

A low concentration impurity junction region, namely an LDD region (not shown) is formed by ion-implanting a low concentration impurity into the semiconductor substrate 71 using the gate 79 and the dummy gate 81 as masks.

A space between the gate 79 and the dummy gate 81 on the device isolation film 73 is filled with an insulating film 85, and a halo implanted region (not shown) is then formed on the semiconductor substrate 71 by performing a halo implant process using the gate 79 and the dummy gate 81 as masks. Here, the halo implanted region has the same shape as the halo implanted region shown in FIG. 4b.

The formation process of the insulating film 85 preferably comprises forming a photosensitive film (not shown) covering the active region, exposing the device isolation film 73 in the device isolation region, and depositing and etching the insulating film.

The halo implant process is performed in the same manner as the process of FIG. 4b, except the rotations being 0°, 90°, 180° and 270°.

Thereafter, source/drain junction regions 83 having an LDD structure are formed according to a process for forming an insulating film spacer (not shown) and a process for forming high concentration impurity junction regions, thereby completing the transistor.

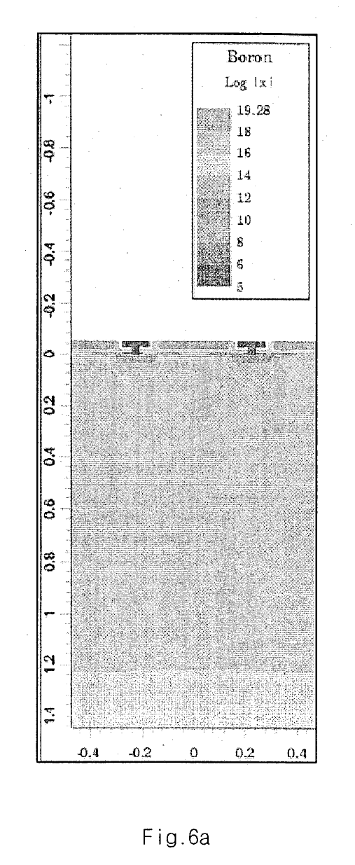

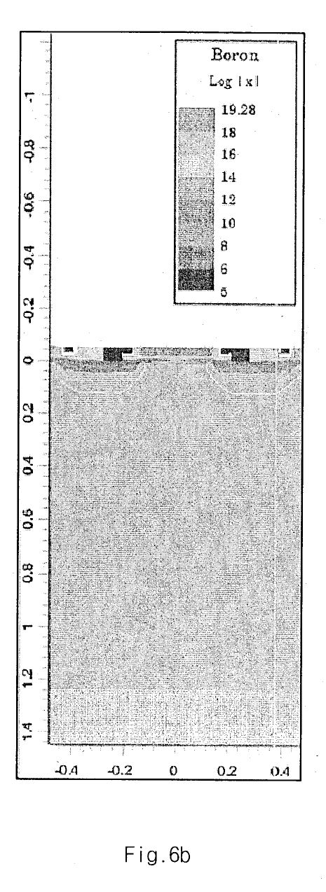

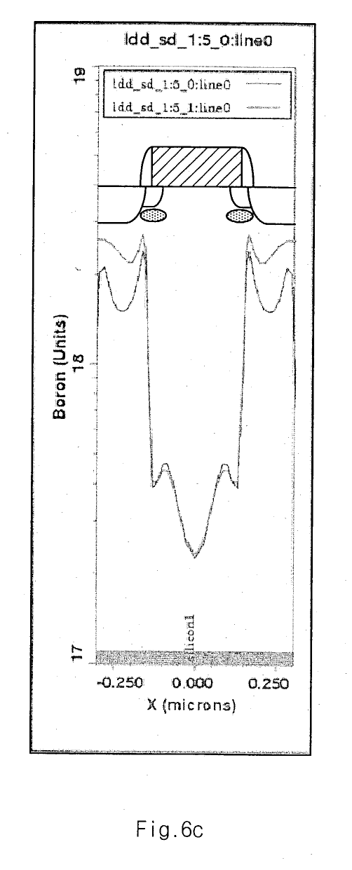

FIGS. 6a to 6c are graphs showing boron concentration according to the depth of the semiconductor substrate of the transistor in accordance with the present invention. A MOSFET wherein a gate length is 0.3 μm and a thickness of an insulating film spacer is 0.06 μm is shown.

Graphs shown in FIGS. 6a and 6b are simulation results of a PN junction of the MOSFET having dummy gates wherein the distance ‘d’ between the gate and the dummy gate is 0.15 μm and 0.3 μm, respectively. It should be noted that when ‘d’ large, the characteristics of the halo implant process in accordance with the present invention is similar to that of the conventional halo implant process.

FIG. 6c shows a halo doping profile in each structure. That is, the super steep halo profile can be embodied using the structure having an appropriate d value.

Here, 0.000 in the x axis denotes the center of the gate, and a portion sharply protruded in the upward direction at both sides denotes the halo doped region.

The upper solid line at both ends shows when ‘d’ is 0.3 μm, and the lower solid line thereof shows when ‘d’ is 0.15 μm.

As discussed earlier, in accordance with the present invention, the transistor of the semiconductor device and the method for forming the same provide sufficient short channel margin, reduced junction leakage current and increased break down voltage. In addition, loading effect is uniformly maintained during the gate etching process by using the dummy gate, and self-aligned contact process can be performed by using the dummy gate, thereby improving characteristics and reliability of the device and achieving a high integration density of the device.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims:

What is claimed is:

1. A transistor of a semiconductor device, comprising:
an device isolation film defining an active region of a semiconductor substrate;
a gate provided in the active region;
dummy gates provided at both sides of the gate, wherein the dummy gates are spaced apart from the gate at a distance of ‘d’ has a height of ‘h’, the dummy gates being positioned to overlap the device isolation film and the active region;
an LDD region formed in the semiconductor substrate between the gate and the dummy gate; and
a halo doped region formed under a portion of the LDD region below the gate and the dummy gates.

2. The transistor according to claim 1, wherein a size of the halo doped region is controlled according to the distance of ‘d’ and the height of ‘h’.

3. A transistor of a semiconductor device, comprising:
an device isolation film defining an active region of a semiconductor substrate;
a gate provided in the active region;
dummy gates provided at both sides of the gate, wherein the dummy gates are spaced apart from the gate at a distance of ‘d’ has a height of ‘h’, the dummy gates being positioned to overlap the device isolation film and the active region;
an insulating film filling a space between the gate and the dummy gate;
an LDD region formed in the semiconductor substrate between the gate and the dummy gate; and
a halo doped region formed under a portion of the LDD region below the gate and the dummy gates.

4. The transistor according to claim 3, wherein a size of the halo doped region is controlled according to the distance of ‘d’ and the height of ‘h’.

5. A method for forming a transistor of a semiconductor device, comprising the steps of:
forming a stacked structure of a gate oxide film and a gate, and dummy gates at both sides of the gate on a semiconductor substrate using a gate mask;
forming an LDD region in the semiconductor substrate using the gate and the dummy gate as masks; and
performing a halo implant process to form a halo doped region under a portion of the LDD region below the gate and the dummy gate using the gate and the dummy gate as masks.

6. The method according to claim 5, wherein the dummy gates are formed in parallel to the gate and spaced apart from the gate by a distance of ‘d’.

7. The method according to claim 5, wherein the dummy gates overlap an active region and an device isolation region of the semiconductor device.

8. The method according to claim 5, wherein the step of performing a halo implant process is a tilt ion-implanting process.

9. The method according to claim 8, wherein the step of performing a halo implant process comprises rotating the semiconductor substrate by 0° and 180° to tilt-implant ions into the semiconductor substrate at the right and left sides of the gate.

10. The method according to claim 5, wherein a size of the halo implanted region is controlled according to the distance of ‘d’ and the height of the dummy gate.

11. A method for forming a transistor of a semiconductor device, comprising the steps of:
forming a stacked structure of a gate oxide film and a gate, and dummy gates at both sides of the gate on a semiconductor substrate using a gate mask;
forming an LDD region in the semiconductor substrate using the gate and the dummy gate as masks;
performing a halo implant process to form a halo doped region under a portion of the LDD region below the gate and the dummy gate using the gate and the dummy gate as masks;
filling a space between the gate and the dummy gate;
forming insulating film spacers on the sidewalls of the gate and the dummy gate; and
ion-implanting a high concentration impurity into the semiconductor substrate by using the gate, the dummy gate and the insulating film spacer as masks to form source/drain junction regions.

12. The method according to claim 11, wherein the dummy gates are formed in parallel to the gate and spaced apart from the gate by a distance of ‘d’.

13. The method according to claim 11, wherein the dummy gates overlap between an active region and an device isolation region of the semiconductor device.

14. The method according to claim 11, wherein the step of performing a halo implant process is a tilt ion-implanting process.

15. The method according to claim 14, wherein the step of performing a halo implant process comprises rotating the semiconductor substrate by 0°, 90°, 180° and 270° rotations.

16. The method according to claim 11, wherein a size of the halo implanted region is controlled according to the distance of ‘d’ and the height of the dummy gate.

17. The method according to claim 11, wherein the step of forming a stacked structure of a gate oxide film and a gate and dummy gates further comprises forming hard mask layers on the gate and the dummy gate.
